(19) United States
(12) Patent Application Publication
(10) Pub. No.: US 2014/0190557 A1
(43) Pub. Date: Jul. 10, 2014

(54) METHOD FOR PRODUCING SOLAR CELL MODULE, SOLAR CELL BACKSIDE SEALING SHEET, AND SOLAR CELL MODULE

(71) Applicants: Shunsuke Kameda, Otsu (JP); Takashi Arai, Otsu (JP); Takao Amioka, Otsu (JP); Yuuka Ashida, Mishima (JP)

(72) Inventors: Shunsuke Kameda, Otsu (JP); Takashi Arai, Otsu (JP); Takao Amioka, Otsu (JP); Yuuka Ashida, Mishima (JP)

(73) Assignees: TORAY ADVANCED FILM CO., LTD., Tokyo (JP); TORAY INDUSTRIES, INC., Tokyo (JP)

(21) Appl. No.: 14/238,608

(22) PCT Filed: Aug. 28, 2012
(86) PCT No.: PCT/JP2012/071650

§ 371 Date: Feb. 12, 2014

(30) Foreign Application Priority Data
Aug. 30, 2011 (JP) 2011-187249

(51) Int. Cl. H01L 31/048; H01L 31/0203

(52) U.S. Cl. CPC H01L 31/0487; H01L 31/0203
USPC 136/251; 438/73; 136/259

(57) ABSTRACT

A method of producing a solar cell module including forming a silicon oxide layer by coating a paint containing at least one of silicate hydrolysis products and silica particles on at least one side of a base film; and adhering said silicon oxide layer with a silicone sealing material layer.

### TECHNICAL FIELD

This disclosure relates to a method of producing a solar cell module capable of withstanding use in harsh outdoor environments over a prolonged period of time and exhibits excellent adhesive strength with a silicone sealing material as well as excellent weather resistance; a solar cell backside sealing sheet; and a solar cell module.

### BACKGROUND

In recent years, there is an increasing concern for depletion of fossil fuels such as oil and coal and it is regarded as an urgent task to develop a technology for securing an alternative energy source to these fossil fuels. Accordingly, various methods including nuclear power generation, hydroelectric power generation, wind power generation and solar power generation have been studied and actually utilized. Photovoltaic power generation, which can directly convert solar energy into electric energy, has been increasingly put into practical use as a semipermanent and pollution-free new energy source and its cost performance in actual use has been remarkably improved, making the expectations as a clean energy source very high.

Solar cells used in solar power generation constitute the heart of a solar power generation system that directly converts solar energy into electric energy and a solar cell is composed of a semiconductor material represented by silicon. With respect to the structure of a solar cell, solar cell elements (hereinafter, referred to as “cells”) are arranged in series or in parallel and packaged in various ways into a unit so as to protect the cells over a prolonged period of 20 years or so. This unit incorporated into a package, which is called a solar cell module, generally has a constitution in which the surface exposed to sunlight is covered with glass, gaps are filled with a sealing material composed of a thermoplastic resin and the backside is protected by a sealing sheet. Therefore, a solar cell module is generally constituted such that a sealing material layer which contains glass and cells and a backside sealing sheet are sequentially laminated.

As the sealing material composed of a thermoplastic resin, an ethylene-vinyl acetate copolymer resin (hereinafter, referred to as “EVA resin”) is often used because of its high transparency and excellent moisture resistance. However, an EVA resin requires time for being heat-cured when used to seal cells and may cause yellowing when exposed to ultraviolet ray for a long time. Therefore, an ultraviolet absorbent is often mixed and this restricts the incoming light, so that there is a problem that the power generation efficiency is reduced. One example of a sealing material that offsets such a problem is silicone. Since silicone has excellent environmental resistance and optical transparency, it can potentially improve the power generation efficiency as compared to a case where an EVA resin is used. Further, since a thermosetting liquid silicone can be heat-cured in a shorter time than an EVA resin, the use of a thermosetting liquid silicone contributes to an improvement in the productivity of a solar cell module.

Meanwhile, a backside sealing sheet is required to have not only properties such as mechanical strength, heat resistance, water resistance, chemical resistance, light-reflecting property, moisture barrier property, thermal adhesiveness with a sealing material, design property and adhesive strength with a silicone-based resin of the outermost layer for mounting of a terminal box, but also excellent weather resistance since it is exposed to ultraviolet light.

One example of a film for backside sealing sheet to be used when an EVA resin is used as a sealing material is a white polyvinyl fluoride film (manufactured by Du Pont, trade name: “Tedlar” (registered trademark)) and a backside sealing sheet having a laminated constitution in which a polyester film is sandwiched by the white polyvinyl fluoride films has been widely used in the solar cell applications.

As a film for backside sealing sheet to be used when an EVA resin is used as a sealing material, one having a constitution in which a polyester film having excellent weather resistance and gas barrier property is laminated can also be mentioned (JP 2002-026354 A (paras. [0008] to [0010]).

In addition, as a measure for improving the adhesive strength, a film on which a heat-bonding layer made of a styrene-olefin copolymer resin (hot-melt adhesive layer) is formed has been proposed (JP 2003-060218 A (paras. [0008] to [0010]).

In cases where a film for a backside sealing sheet in which a polyester film having excellent weather resistance and gas barrier property is laminated is employed as the film for backside sealing sheet disclosed in JP 2002-026354 A (paras. [0008] to [0010] that is used when an EVA resin is used as a sealing material, there is a problem that the adhesiveness between a polyester film represented by polyethylene terephthalate resin and an EVA resin is generally not very high.

The film disclosed in JP 2003-060218 A (paras. [0008] to [0010], on which a heat-bonding layer made of a styrene-olefin copolymer resin (hot-melt adhesive layer) is formed, improves the adhesive strength; however, the strength cannot be considered sufficient and there is also a concern in terms of the durability of the strength.

Meanwhile, when using silicone as a sealing material, since the above-described films for backside sealing sheet have poor adhesion with silicone, it is required to develop a new backside sealing sheet suitable for a silicone sealing material. In addition, although the above-described backside sealing sheet having a constitution in which a polyester film is sandwiched by polyvinyl fluoride films has excellent weather resistance, its high price may present an obstacle to price reduction of a solar cell module.

It could therefore be helpful to provide a method of producing a solar cell module having excellent adhesive strength with a silicone sealing material and excellent weather resistance; a solar cell backside sealing sheet; and a solar cell module.

### SUMMARY

We thus provide a method of producing a solar cell module comprising: forming a silicon oxide layer by coating a paint containing at least one of silicate hydrolysis products and silica particles on at least one side of a base film; and adhering the silicon oxide layer with a silicone sealing material layer.

Our solar cell backside sealing sheet comprises a silicon oxide layer formed by coating a paint containing at least one of silicate hydrolysis products and silica particles on at least one side of a base film.

The solar cell module is a solar cell module in which the above-described silicon oxide layer and a silicone sealing material layer are directly laminated.

In the method of producing a solar cell module, it is preferred that the above-described silicate be butyl silicate.

In the method of producing a solar cell module, it is preferred that the above-described base film contain an inorganic pigment.

In the method of producing a solar cell module, it is preferred that the above-described base film comprise an ultraviolet absorbent-containing resin layer on the opposite side of the surface on which the above-described silicon oxide layer is formed

In the method of producing a solar cell module, it is preferred that the above-described base film comprise an ultraviolet absorbent-containing resin layer and the surface on which the above-described silicon oxide layer is formed be on the side of the resin layer.

A method of producing a solar cell module which is capable of withstanding the use in harsh outdoor environments over a prolonged period of time and exhibits excellent adhesive strength with a silicone sealing material as well as excellent weather resistance; a solar cell backside sealing sheet; and a solar cell module are obtained.

### DETAILED DESCRIPTION

The method of producing a solar cell module comprises: forming a silicon oxide layer by coating a paint containing at least one of silicate hydrolysis products and silica particles on at least one side of a base film; and adhering the silicon oxide layer with a silicone sealing material layer. By applying this production method, excellent adhesive strength is attained between a base film and a silicone sealing material layer and a solar cell module having excellent weather resistance can be obtained.

### Base Film

In the solar cell backside sealing sheet, as the base film on which a silicon oxide layer is arranged on the surface coming in contact with a silicone sealing material layer, a variety of resin films can be used. Specific examples thereof include polyester resin films composed of polyethylene terephthalate (PET), polyethylene naphthalate (PEN) or the like; resin films composed of polycarbonate, polymethyl methacrylate, polyacrylate, polypropylene, polyethylene or the like; and resin films composed of a mixture of these resins. Thereamong, polyester resin films are preferred because of their excellent strength, dimensional stability and thermal stability, and polyethylene terephthalate films such as PET and PEN are particularly preferred because they are inexpensive. Further, the polyester resin may be a copolymer as well and examples of a copolymer component that can be used include diol components such as propylene glycol, diethylene glycol, neopentyl glycol and cyclohexane dimethanol; and dicarboxylic acid components such as isophthalic acid, adipic acid, azelaic acid, sebacic acid and ester-forming derivatives thereof.

From the standpoint that the solar cell backside sealing sheet is used in an environment where it is directly exposed to the ambient air, it is preferred that the base film be a resin film having excellent hydrolysis resistance, that is, a hydrolysis-resistant film. Normally, a polyester resin film is formed by using a so-called polymer prepared by condensation polymerization of monomers and such a polyester resin film contains an oligomer, which is regarded as an intermediate between a monomer and a polymer, in an amount of 1.5 to 2% by mass or so. One representative example of an oligomer is a cyclic trimer and a film having a high content thereof, when exposed to an outdoor environment or the like over a long time, experiences a reduction in the mechanical strength and generates cracks, fractures and the like as hydrolysis caused by rainwater and the like progresses. In contrast to this, in a hydrolysis-resistant film, by using a polyester resin containing a cyclic trimer obtained by a solid-phase polymerization process in an amount of 1.0% by mass or less as a starting material to form a polyester resin film, hydrolysis in high-temperature and high-humidity conditions can be inhibited so that a film having excellent heat resistance and weather resistance can be obtained. The above-described cyclic trimer content can be determined by, for example, a method in which a solution prepared by dissolving 100 mg of the polymer of interest into 2 mL of o-chlorophenol is subjected to liquid chromatography to measure the content of a cyclic trimer (% by mass) with respect to the resin mass.

Further, as the resin film constituting the solar cell backside sealing sheet, for example, a resin film to which an additive(s) such as an antistatic agent, an ultraviolet absorbent, a stabilizer, an antioxidant, a plasticizer, a lubricant, a filler agent and/or a coloring pigment is/are added as required within the range which does not have an adverse affect can also be used.

Specific examples of such a resin film to which an additive is added include white films formed from a resin material prepared by kneading a white pigment into any of the above-described resin films composed of polyester such as polyethylene terephthalate (PET) or polyethylene naphthalate (PEN), polycarbonate, polymethyl methacrylate, polyacrylate, polypropylene, polyethylene or the like or a resin film composed of a mixture of these resins. As the white pigment, an inorganic pigment such as titanium oxide or zinc oxide can be preferably used and, by kneading such a white pigment, a white film having a whiteness of not less than 80% and an opacity of not less than 80% can be obtained. Such a white film is used for the purpose of reflecting the light reaching the back sheet to assist the energy conversion in a semiconductor element and it is preferred that the white film be arranged in a layer close to the cell. The white film preferably used as the base film is arranged for the purpose of reflecting sunlight to improve the power generation efficiency. The white film has a reflectance of preferably 30% or higher, more preferably 40% or higher, still more preferably 50% or higher, at a wavelength, λ, of 550 nm. Among the above-described films, polyester resin films composed of PET, PEN or the like are preferred because of their excellent strength, dimensional stability and thermal stability, and polyethylene terephthalate films are particularly preferred because they are inexpensive. The polyester resin constituting the polyester resin film is represented by, for example, but not particularly restricted to, polyethylene terephthalate in which 80 mol % or more of the structural units is ethylene terephthalate, polyethylene naphthalate in which 80 mol % or more of the structural units is ethylene naphthalate and polylactic acid in which 80 mol % or more of the structural units is lactic acid. Further, the polyester resin may also be a copolymer and examples of a copolymer component that can be used include diol components such as propylene glycol, diethylene glycol, neopentyl glycol and cyclohexane dimethanol; and dicarboxylic acid components such as isophthalic acid, adipic acid, azelaic acid, sebacic acid and ester-forming derivatives thereof.

The thickness of the resin film for the above-described solar cell backside sealing sheet is not particularly restricted. However, taking the voltage resistance, the cost and the like of the sealing sheet into consideration, it is preferably in the range of 1 to 250 μm.

Further, as the base film, a moisture barrier film on which at least one inorganic oxide layer is formed by a vapor deposition method or the like for the purpose of providing moisture barrier property may be used as well. The term “moisture barrier film” used herein refers to a resin film having a moisture permeability, which is determined by the method B prescribed in JIS K 7129 (2000), of not higher than 5 g/(m²·day). Examples of such a moisture barrier film include those films in which at least one metal thin film layer or inorganic oxide layer is formed by a vapor deposition method or the like on at least one side of a polyester resin film composed of polyethylene terephthalate (PET), polyethylene naphthalate (PEN) or the like or an olefin-based film composed of polypropylene. However, since the solar cell backside sealing sheet is required to have high electric insulation, an inorganic oxide layer is preferred over a conductive metal thin film layer. The gas barrier property of a film on which an inorganic oxide layer is formed by vapor deposition or the like is attributed to at least the thermal dimensional stability of the polyester resin film used as the base material. Therefore, the polyester resin film is preferably a bi-axially extended film.

Further, as required, the resin film may also be subjected to, for example, a discharge treatment such as corona discharge or plasma discharge, or a surface treatment such as an acid treatment.

Still further, on the resin film, as required, the below-described weather-resistant and ultraviolet-shielding resin layer may be laminated as well.

### Silicon Oxide Layer

In the method of producing a solar cell module, a silicon oxide layer is formed by coating a paint containing at least one of silicate hydrolysis products and silica particles on at least one side of the above-described base film. As the silicate, ethyl silicate, propyl silicate and butyl silicate are preferred and butyl silicate is more preferred.

The paint used in this process is dissolved in a solvent such as isopropyl alcohol, n-butyl alcohol or toluene and the resultant is then coated and dried, thereby a silicon oxide layer can be formed.

A silicon oxide layer formed in this manner functions as an adhesion-promoting layer for a sealing material. In the formation of a solar cell module, it is preferred that the silicon oxide layer be adhered with a silicone sealing material layer in a thermo-compression bonding step, and the adhesive strength is required to be maintained even in an environment where the solar cell module is exposed outdoors over a prolonged period of time. Therefore, it is preferred that the adhesion-promoting layer for the sealing material be composed of a weather-resistant material and, from this standpoint, a silicon oxide layer is preferably applied.

The thickness of the silicon oxide layer is not particularly restricted. However, taking the productivity and the cost into consideration, it is preferably in the range of 0.05 to 0.4 μm.

The method of forming such a silicon oxide layer on the base film should not be particularly restricted and a variety of known coating methods can be employed. For example, a roll coating method, a dip coating method, a bar coating method, a die coating method, a gravure roll coating method and a combination of these methods can be utilized. Thereamong, a gravure roll coating method is preferred since it improves the stability of a coating layer-forming composition.

### Other Additives

Further, in the silicon oxide-containing coating solution, as long as its properties are not deteriorated, for example, a heat stabilizer, an antioxidant, a reinforcing agent, an antidegradant, an antiweathering agent, a flame retardant, a plasticizer, a release agent, a lubricant, a cross-linking aid, a pigment dispersant, a defoaming agent, a leveling agent, an ultraviolet absorbent, a light stabilizer, a thickener, an adhesion-improving agent and/or a delustering agent may also be incorporated.

Examples of a heat stabilizer, antioxidant and antidegradant that can be used include hindered phenols, phosphorus compounds, hindered amines, sulfur compounds, copper compounds, alkali metal halides, and mixtures thereof.

Examples of a reinforcing agent that can be used include clay, talc, calcium carbonate, zinc carbonate, wollastonite, silica, alumina, magnesium oxide, calcium silicate, sodium aluminate, sodium aluminosilicate, magnesium silicate, glass balloon, carbon black, zinc oxide, zeolite, hydrotalcite, metal fiber, metal whisker, ceramic whisker, potassium titanate whisker, boron nitride, graphite, glass fiber and carbon fiber.

Examples of an ultraviolet absorbent that can be used include salicylic acid-based, benzophenone-based, benzotriazole-based and cyanoacrylate-based ultraviolet absorbents. Specific examples thereof include salicylic acid-based ultraviolet absorbents such as p-t-butylphenyl salicylate and p-octylphenyl salicylate; benzophenone-based ultraviolet absorbents such as 2,4-dihydroxybenzophenone, 2-hydroxy-4-methoxybenzophenone, 2-hydroxy-4-methoxy-5-sulfobenzophenone, 2,2′,4,4′-tetrahydroxybenzophenone and bis(2-methoxy-4-hydroxy-5-benzoylphenyl)methane; benzotriazole-based ultraviolet absorbents such as 2-(2′-hydroxy-5′-methylphenyl)benzotriazole, 2-(2′-hydroxy-5′-methylphenyl)benzotriazole and 2,2′-methylenebis[4-(1,1,3,3-tetramethylbutyl)-6-(2H-benzotriazole-2-yl)phenol]; cyanoacrylate-based ultraviolet absorbents such as ethyl-2-cyano-3,3′-diphenylacrylate; other ultraviolet absorbents such as 2-(4,6-diphenyl-1,3,5-triazine-2-yl)-5-[(hexyl)oxy]-phenol; and denaturation products, polymers and derivatives of these ultraviolet absorbents.

Examples of a light stabilizer that can be used include hindered amine-based light stabilizers. Specific examples thereof include bis(1,2,2,6,6-pentamethyl-4-piperidyl){[3,5-bis(1,1-dimethylethyl)-4-hydroxyphenyl]methyl}butylmalonate, bis(1,2,2,6,6-pentamethyl-4-piperidyl)sebacate, methyl(1,2,2,6,6-pentamethyl-4-piperidyl)sebacate and decanedioic acid-bis[2,2,6,6-tetramethyl-1-octyloxy]-4-piperidyl]ester, as well as denaturation products, polymers and derivatives of these compounds.

### Solar Cell Backside Sealing Sheet

A sheet obtained by forming a silicon oxide layer on a base film can be used as a solar cell backside sealing sheet. The solar cell backside sealing sheet may also take the form where other resin film is laminated on the opposite side of the surface of the base film on which the silicon oxide layer is formed. As a method of attaining such a laminated form, a lamination process using a known dry lamination method can be applied. In the lamination process using a dry lamination method, an adhesive prepared by diluting two resins of a base compound and a cross-linking agent with a diluent solvent is used. Specifically, it is preferred to use a polyether-polyurethane resin, a polyester-polyurethane resin, a polyester resin, a polyepoxy resin or the like as the base compound and an isocyanate group-containing polymer, which has excellent reactivity with active hydroxyl groups and quickly exhibits its reaction rate and initial adhesive strength, as the cross-linking agent. It is noted here, however, that an adhesive layer formed from such an adhesive is required, for example, not to induce delamination caused by deterioration of the adhesive strength in a long-term outdoor use and not to cause yellowing that leads to a reduction in the light reflectance. From this standpoint, the resin used in the formation of an adhesive layer is preferably an aliphatic resin or alicyclic resin which contains no or only a small amount of an aromatic ring. Further, the thickness of the adhesive layer is preferably in the range of 1 to 10 μm. When the thickness of the adhesive layer is in this preferred range, sufficient adhesive strength is attained while there is no increase in the production cost.

A solar cell backside sealing sheet is required to have a variety of properties represented by, for example, moisture barrier, light reflection, long-term moist heat resistance and weathering durability, adhesive strength with a sealing material, and electric insulation. At present, to satisfy these required properties, various companies provide various sheet designs (laminate designs) that combine a variety of functional films with processing techniques such as vapor deposition and wet coating based on the concept of functional partition.

A solar cell backside sealing sheet satisfying the variety of required properties may also be prepared by laminating, on a base film, one or more of a hydrolysis-resistant film, a white film, a film having a vapor-deposited inorganic oxide layer and a weather-resistant and ultraviolet-shielding outer resin layer (e.g., a film or a resin-coated layer). Preferably, the base film of the solar cell backside sealing sheet has a weather-resistant and ultraviolet-shielding resin layer on the opposite side of the surface on which a silicon oxide layer is formed. Alternatively, the solar cell backside sealing sheet may have a constitution in which the base film has a weather-resistant and ultraviolet-shielding resin layer and a silicon oxide layer is formed thereon. Particularly, a design in which a hydrolysis-resistant film is used as the base film and a hydrolysis-resistant and weather-resistant film, on which a weather-resistant and ultraviolet-shielding resin layer is formed, is laminated on the base film, or a design in which the base film has a weather-resistant and ultraviolet-shielding resin layer (hereinafter, may be simply referred to as “resin layer”) is preferred.

### Weather-Resistant and Ultraviolet-Shielding Resin Layer

Examples of the weather-resistant and ultraviolet-shielding resin layer include ultraviolet absorbent-containing resin layers. As a resin for forming an ultraviolet absorbent-containing resin layer, for example, a fluorine-containing resin, an acrylic resin, a polyester resin, a polyolefin resin or a polyamide resin can be used. Specific examples of the fluorine-containing resin include polytetrafluoroethylene (PTFE), polyvinylidene difluoride (PVDF), polyvinyl fluoride (PVF), ethylene-tetrafluoroethylene copolymer resin (ETFE), ethylene-chlorotrifluoroethylene copolymer resin (ECTFE) and tetrafluoroethylene-perfluoroalkyl vinyl ether copolymer resin (PFA) and specific examples of the acrylic resin include those which are obtained by cross-linking polymethyl methacrylate, polyacrylate or acrylic polyol resin using a variety of cross-linking agents. Further, specific examples of the polyester resin include polyethylene terephthalate (PET), polyethylene naphthalate (PEN) and polybutylene terephthalate (PBT), specific examples of the polyolefin resin include polypropylene, polyethylene, ethylene-vinyl acetate (EVA) and cyclic olefin resins, and specific examples of the polyamide resin include nylon 6, nylon 6,6, nylon 11 and nylon 12.

As an ultraviolet absorbent to be blended in these resins, an inorganic ultraviolet absorbent or an organic ultraviolet absorbent is used. Examples of the inorganic ultraviolet absorbent include titanium oxide and zinc oxide that can also be used as white pigments; and carbon blacks that can also be used as black pigments, and examples of the organic ultraviolet absorbent include salicylic acid-based, benzophenone-based, benzotriazole-based and cyanoacrylate-based ultraviolet absorbents. Specific examples of the organic ultraviolet absorbents include salicylic acid-based ultraviolet absorbents such as p-t-butylphenyl salicylate and p-octylphenyl salicylate; benzophenone-based ultraviolet absorbents such as 2,4-dihydroxybenzophenone, 2-hydroxy-4-methoxybenzophenone, 2-hydroxy-4-methoxy-5-sulfobenzophenone, 2,2′,4,4′-tetrahydroxybenzophenone and bis(2-methoxy-4-hydroxy-5-benzoylphenyl)methane; benzotriazole-based ultraviolet absorbents such as 2-(2′-hydroxy-5′-methylphenyl)benzotriazole, 2-(2′-hydroxy-5′-methylphenyl)benzotriazole and 2,2′-methylenebis[4-(1,1,3,3-tetramethylbutyl)-6-(2H-benzotriazole-2-yl)phenol]; cyanoacrylate-based ultraviolet absorbents such as ethyl-2-cyano-3,3′-diphenylacrylate; other ultraviolet absorbents such as 2-(4,6-diphenyl-1,3,5-triazine-2-yl)-5-[(hexyl)oxy]-phenol; and denaturation products, polymers and derivatives of these ultraviolet absorbents. Since the solar cell module is used outdoor over a prolonged period of 20 years or longer depending on the case, the ultraviolet absorbent to be used is preferably an inorganic ultraviolet absorbent from the standpoint of the durability.

### Light Stabilizer Used in Weather-Resistant and Ultraviolet-Shielding Resin Layer

Further, examples of a light stabilizer preferably used in the above-described weather-resistant and ultraviolet-shielding resin layer in the same manner include hindered amine-based light stabilizers. Specific examples thereof include bis(1,2,2,6,6-pentamethyl-4-piperidyl) {[3,5-bis(1,1-dimethylethyl)-4-hydroxyphenyl]methyl}butylmalonate, bis(1,2,2,6,6-pentamethyl-4-piperidyl)sebacate, methyl(1,2,2,6,6-pentamethyl-4-piperidyl)sebacate and decanedioic acid-bis[2,2,6,6-tetramethyl-1-octyloxy]-4-piperidyl]ester, as well as denaturation products, polymers and derivatives of these compounds.

Among the above-described resins, an acrylic polyol resin obtained by copolymerizing an ultraviolet absorbent and a light stabilizer is preferably used as the resin layer. Further, it is more preferred that the resin layer be formed by mixing an acrylic polyol resin, which is obtained by copolymerizing an ultraviolet absorbent and a light stabilizer, with an inorganic ultraviolet absorbent, because the ultraviolet-shielding performance is further improved.

### Other Additives Usable in Weather-Resistant and Ultraviolet-Shielding Resin Layer

Further, in the above-described weather-resistant and ultraviolet-shielding resin layer, for example, an additive(s) such as an antistatic agent, a stabilizer, an antioxidant, a reinforcing agent, a plasticizer, a lubricant, a filler agent and/or a coloring agent may be incorporated as required within the range which does not have adverse effects. Examples of a heat stabilizer, antioxidant and antidegradant that can be used include hindered phenols, phosphorus compounds, hindered amines, sulfur compounds, copper compounds, alkali metal halides, and mixtures thereof.

Examples of a reinforcing agent include clay, talc, calcium carbonate, zinc carbonate, wollastonite, silica, alumina, magnesium oxide, calcium silicate, sodium aluminate, sodium aluminosilicate, magnesium silicate, glass balloon, carbon black, zinc oxide, zeolite, hydrotalcite, metal fiber, metal whisker, ceramic whisker, potassium titanate whisker, boron nitride, graphite, glass fiber and carbon fiber.

As an example of the weather-resistant and ultraviolet-shielding resin layer, the following films and coating layers are described. The films include titanium oxide- or carbon black-containing polyvinyl fluoride films, polyvinylidene difluoride films, polyethylene terephthalate films, polyethylene films and ethylene-vinyl acetate films. Further, the coating layers include those which are formed by using a tetrafluoroethylene-based copolymer resin-containing paint that contains titanium oxide or a carbon black or by using a paint containing an acrylic polyol resin and a polyisocyanate resin.

Thereamong, as a means of attaining a solar cell backside sealing sheet satisfying both the production cost and the ultraviolet resistance, a coating layer which is formed by using a tetrafluoroethylene-based copolymer resin-containing paint that contains titanium oxide or a carbon black or by using a paint containing an acrylic polyol resin and a polyisocyanate resin is preferred.

### Method of Producing Weather-Resistant and Ultraviolet-Shielding Resin Layer

The method of laminating the above-described weather-resistant and ultraviolet-shielding resin layer is not particularly restricted and examples thereof include a method of laminating by melt extrusion; a coating method in which a liquid paint containing other resin and/or an additive(s) is coated and then cured by heat, light, electron beam or the like; and the above-described dry lamination method in which the weather-resistant and ultraviolet-shielding resin layer is laminated with a film containing other resin and/or an additive(s) using an adhesive.

For example, in cases where the weather-resistant and ultraviolet-shielding resin layer is formed by a coating method, as a solvent of a coating solution, for example, toluene, toluene, xylene, ethyl acetate, butyl acetate, acetone, methyl ethyl ketone, methyl isobutyl ketone, tetrahydrofuran, dimethylformamide, dimethylacetamide, methanol, ethanol or water can be used, and the properties of the coating solution may be of either an emulsion type or a dissolved type.

The method of forming the weather-resistant and ultraviolet-shielding resin layer should not be particularly restricted and a known coating method can be employed. As the coating method, a variety of methods can be applied and, for example, a roll coating method, a dip coating method, a bar coating method, a die coating method, a gravure roll coating method and a combination of these methods can be utilized. Thereamong, a gravure roll coating method is preferred since it improves the stability of a coating layer-forming composition.

### Solar Cell Module

When using a solar cell backside sealing sheet prepared in the above-described manner in a solar cell module, a silicon oxide layer of the solar cell backside sealing sheet is adhered to the silicone sealing material layer of the solar cell module, thereby incorporating the solar cell backside sealing sheet into the solar cell module.

### EXAMPLES

The method of producing a solar cell module will now be concretely described by way of examples thereof. In the examples below, “parts” means “parts by mass” unless otherwise specified.

### <Evaluation Methods of Properties>

The methods used for evaluation of the properties are as follows.

### (1) Measurement of Coating Amount

The coating amount of a weather-resistant and ultraviolet-shielding resin layer (resin layer) was measured by the following procedure. After forming a resin layer, a test piece having an area of 500 cm² was cut out and the mass of the test piece was defined as “mass A”. Then, the resin layer was dissolved in methyl ethyl ketone and peeled off from the test piece. The mass of the resulting test piece was measured again and defined as “mass B”. Thereafter, the coating amount per unit area was calculated based on the equation below. This measurement of coating amount was performed for three test pieces and the average thereof was defined as the coating amount.

Coating amount [g/m²]=(Mass A−Mass B)×20

(2) Measurement of Adhesive Strength with Sealing Material Layer

In accordance with JIS K 6854-2 (1999), the adhesive strength was measured between the silicone sealing material layer and the base film of each mock solar cell module sample prepared in the respective examples. In the adhesive strength test, the width of each test piece was set at 10 mm and two test pieces were each measured once. The average of the two measurements was defined as the value of the adhesive strength.

### (3) Evaluation of Moist Heat Resistance

Using a thermo-hygrostat oven manufactured by Espec Corp., each mock solar cell module was subjected to a 1,000-hour moist heat treatment in an environment of 85° C. and 85% RH. Then, the adhesive strength between the sealing material layer and the backside sealing sheet was measured.

### (4) Evaluation of Ultraviolet Resistance

Using Eye Super UV Tester SUV-W151 manufactured by Iwasaki Electric Co., Ltd., the glass surface side or the outer layer surface (backside sealing sheet) side of each mock solar cell module was subjected to ultraviolet irradiation in an atmosphere of 60° C. and 50% RH at an ultraviolet intensity of 160 mW/cm² for 240 hours. The b-value of the color system was measured before and after the ultraviolet irradiation.

### Preparation of Paint for Formation of Silicon Oxide Layer (Paint 1)

In accordance with the formulation shown in the column “Preparation 1” of Table 1, n-butyl silicate and ethanol were mixed and stirred for 20 minutes and 0.1N hydrochloric acid was slowly added dropwise thereto such that a temperature of 25° C. or lower was maintained. The resultant was stirred for 2 hours and then stored and aged in a covered container for 12 to 24 hours, thereby obtaining a preparation 1. Next, in a separate container, in accordance with the formulation shown in the column “Preparation 2” of Table 1, isopropyl alcohol, n-butyl alcohol and toluene were mixed and stirred for 15 minutes. Then, “Toray Silicone” (registered trademark) SH190 manufactured by Dow Corning Toray Co., Ltd. was further mixed thereto and stirred for 30 minutes to obtain a preparation 2. The thus obtained preparations 1 and 2 were mixed and stirred for 30 minutes to obtain a paint 1 having a solid concentration of 1% by mass.

TABLE 1

| | | | Paint 1 |
|---|---|---|---|
| Preparation 1 | n-butyl silicate | parts by mass | 3.77 |
| | ethanol | parts by mass | 1.86 |
| | 0.1N hydrochloric acid | parts by mass | 0.96 |
| Preparation 2 | iso-propyl alcohol | parts by mass | 46.60 |
| | n-butyl alcohol | parts by mass | 23.40 |
| | toluene | parts by mass | 23.40 |
| | “Toray Silicone” SH190 | parts by mass | 0.01 |

### Preparation of Paint for Formation of Silicon Oxide Layer (Paint 2)

A polysilicate-based coating agent, DM-30 manufactured by Ryowa Corporation (solid concentration: 1% by mass), was used as a paint 2.

### Preparation of Paint for Formation of Weather-Resistant Coating Layer (Paint 3)

### (i) Preparation of Base Compound

In accordance with the formulation shown in the column “Base compound” of Table 2, “HALS Hybrid Polymer” (registered trademark) BK1 (solid concentration: 40% by mass) manufactured by Nippon Shokubai Co., Ltd., which is a coating agent produced by cross-linking an ultraviolet absorbent and a light stabilizer (HALS) to an acrylic polyol resin, was mixed with a coloring pigment and a solvent at once and the resultant was dispersed using a bead mill. Then, a plasticizer was added thereto to obtain a base compound of a paint for formation of a weather-resistant and ultraviolet-shielding resin layer, which had a solid concentration of 51% by mass.

### (ii) Preparation of Paint 3

To the thus obtained base compound, “Desmodur” (registered trademark) N3300 (solid concentration: 100% by mass), which is a nurate-type hexamethylene diisocyanate resin manufactured by Sumitomo Bayer Urethane Co., Ltd., was added in an amount which had been calculated in advance such that the mass ratio of the base compound and “Desmodur” in the resulting paint for formation of a resin layer became 100/4. Further, the resulting mixture was stirred for 15 minutes with a diluent (n-propyl acetate) which was weighed in an amount calculated in advance such that the resulting solid concentration became 20% by mass (resin solid concentration), thereby obtaining a paint 3 having a solid concentration of 20% by mass (resin solid concentration).

It is noted here that the following products were used as the coloring pigment and the plasticizer in the above-described preparation.

White pigment: titanium oxide particle, JR-709, manufactured by Tayca Corporation

Plasticizer: polyester-based plasticizer manufactured by DIC Corporation, “Polycizer” (registered trademark) W-220EL

TABLE 2

| | | | | Paint 3 |
|---|---|---|---|---|
| Base | Coating | “Hals Hybrid” ™ polymer BK1 manufactured by Nippon Shokubai Co., Ltd. | parts by | 42.5 |
| compound | agent | (Solid content concentration: 40 mass %) | mass | |
| | Coloring | Titanium oxide particle JR-709 manufactured by Tayca Corporation | parts by | 30.0 |
| | pigment | | mass | |
| | Plasticizer | Polyester plasticizer manufactured by DIC Corporation | parts by | 4.0 |
| | | “Polycizer” ™ W-220EL | mass | |
| | Solvent | ethyl acetate | parts by | 23.5 |
| | | | mass | |

| | | |
|---|---|---|
| Solid content concentration of base compound of the paint | mass % | 51.0 |

| | | | |
|---|---|---|---|
| Curing agent | “Desmodur” ™ manufactured by Sumika Bayer Urethane Co., Ltd. | parts by | 4.0 |
| | N3300 (Solid content concentration: 100 mass %) | mass | |
| Diluent | n-propyl acetate | parts by | 171.0 |
| | | mass | |

| | | |
|---|---|---|
| Solid content concentration of the paint 3 | mass % | 20.0 |

### Preparation of Adhesive for Dry Lamination

First, 36 parts of “Dicdry” (registered trademark) TAF-300, which is a moist heat-resistant dry lamination agent manufactured by DIC Corporation that contains, as a main component, a resin containing a hydroxyl group in its structure as a site of reaction with a curing agent, 3 parts of TAF Hardener AH-3 manufactured by DIC Corporation, which contains a hexamethylene diisocyanate-based resin as a main component and was used as a curing agent, and 30 parts by mass of ethylene acetate were weighed and mixed by stirring for 15 minutes to obtain an adhesive for dry lamination which had a solid concentration of 30% by mass. After laminating films by a dry lamination method using the thus obtained adhesive, as described in each example below, the resulting laminate was subjected to aging, thereby allowing hydroxyl groups and isocyanate groups to undergo cross-linking reactions to form urethane bonds.

### Example 1

As a base film, “LUMIRROR” (registered trademark) X10S (125 μm) manufactured by Toray Industries, Inc., which is a hydrolysis-resistant polyethylene terephthalate film having a cyclic trimer content of 1% by mass or less, was prepared. On one side of this base film, a corona treatment was performed and the paint 1 was coated using a wire bar and then dried at 125° C. for 60 seconds to form a silicon oxide layer such that the post-drying coating amount thereof became 0.1 g/m² (thickness: 0.1 μm). In this manner, a solar cell backside sealing sheet 1 (abbreviated as “Sealing sheet 1” in Tables 3 and 4) was prepared. Next, on a 3 mm-thick semi-reinforced glass, a silicone resin (a two-liquid cured-type resin having a tensile elastic modulus of 0.09 MPa (based on JIS K 7161(1994)), a tensile strength of 0.4 MPa (based on JIS K 7161(1994)), a refractive index of 1.402 (based on JIS K 0062(1992)) and a specific gravity (25° C.) of 0.97 (based on JIS Z 8807(1976))) was laminated, and the thus obtained solar cell backside sealing sheet 1 was further laminated such that the inter layer surface thereof (the surface of the base film on which the silicon oxide layer was formed) came into contact with the silicone resin. The resultant was vacuumed under heating at 120° C. for 30 seconds using a vacuum laminator and then subjected to a 5-minute press treatment, thereby preparing a mock solar cell module.

### Example 2

A solar cell backside sealing sheet 2 (abbreviated as “Sealing sheet 2” in Tables 3 and 4) was prepared in the same manner as in Example 1, except that the paint 2 for formation of a silicon oxide layer was coated in place of the paint 1 for formation of a silicon oxide layer and the drying temperature was set at 80° C. A mock solar cell module was also prepared in the same manner as in Example 1, except that the solar cell backside sealing sheet 2 was used.

### Example 3

On the side opposite to the surface of the solar cell backside sealing sheet 1 prepared by the method according to Example 1 on which the silicon oxide layer was formed, a corona treatment was performed and the paint 3 was coated using a wire bar and then dried at 150° C. for 30 seconds to form a weather-resistant and ultraviolet-shielding resin layer such that the post-drying coating amount thereof became 3.0 g/m², thereby preparing a solar cell backside sealing sheet 3 (abbreviated as “Sealing sheet 3” in Tables 3 and 4). A mock solar cell module was also prepared in the same manner as in Example 1, except that the solar cell backside sealing sheet 3 was used.

### Example 4

Using “LUMIRROR” (registered trademark) E20 (125 μm), which is a white polyethylene terephthalate film manufactured by Toray Industries, Inc., as a base film, a silicon oxide layer was formed in the same manner as in Example 1. Then, separately, “LUMIRROR” (registered trademark) X10S (125 μm) manufactured by Toray Industries, Inc., which is a hydrolysis-resistant polyethylene terephthalate film having a cyclic trimer content of 1% by mass or less, was prepared as a lamination film. On one side of this lamination film, a corona treatment was performed and the paint 3 was coated using a wire bar and then dried at 150° C. for 30 seconds to form a weather-resistant and ultraviolet-shielding resin layer such that the post-drying coating amount thereof became 3.0 g/m². Thereafter, on the side opposite to the surface of the white film on which the silicon oxide layer was formed, the adhesive for dry lamination was coated using a wire bar and dried at 80° C. for 45 seconds to form a dry lamination adhesive layer such that the post-drying coating amount thereof became 5.0 g/m² (thickness: 5 μm). Subsequently, the side opposite to the surface of the lamination film on which the weather-resistant and ultraviolet-shielding resin layer was formed was further laminated and the resultant was subjected to dry lamination, thereby preparing a solar cell backside sealing sheet 4 (abbreviated as “Sealing Sheet 4” in Tables 3 and 4). A mock solar cell module was also prepared in the same manner as in Example 1, except that the solar cell backside sealing sheet 4 was used.

### Example 5

A solar cell backside sealing sheet 5 (abbreviated as “Sealing Sheet 5” in Tables 3 and 4) was prepared in the same manner as in Example 1, except that the paint 3 was coated in place of the paint 1 for formation of a silicon oxide layer and then dried at 150° C. for 30 seconds to form a weather-resistant and ultraviolet-shielding resin layer such that the post-drying coating amount thereof became 3.0 g/m²; and that the paint 1 was further coated on the thus formed resin layer using a wire bar and then dried at 125° C. for 60 seconds to form a silicon oxide layer such that the post-drying coating amount thereof became 0.1 g/m² (thickness: 0.1 μm). A mock solar cell module was also prepared in the same manner as in Example 1, except that the solar cell backside sealing sheet 5 was used.

### Comparative Example 1

A mock solar cell module was prepared in the same manner as in Example 1, except that “LUMIRROR” (registered trademark) X10S (manufactured by Toray Industries, Inc., 125 μm) was used as a solar cell backside sealing sheet 6 (abbreviated as “Sealing sheet 6” in Tables 3 and 4) without forming a silicon oxide layer thereon.

For the mock solar cell modules that were obtained in Examples 1 to 5 and Comparative Example 1, their properties were evaluated by the above-described evaluation methods. The results are shown in Tables 3 and 4.

TABLE 3

| | | | | | Weather resistant | |
|---|---|---|---|---|---|---|
| | | | Silicon oxide layer | | coating layer | |
| | | | | Coating | | Coating |
| | | | | amount | | amount |
| Example No. | Sealing sheet | Sealing sheet costitution | Paint | [g/m²] | Paint | [g/m²] |
| Example 1 | Sealing sheet 1 | Silicon oxide layer 1/“LUMIRROR” ™ XS10S (125 μm) | Paint 1 | 0.1 | absence | — |
| Example 2 | Sealing sheet 2 | Silicon oxide layer 2/“LUMIRROR” ™ XS10S (125 μm) | Paint 2 | 0.1 | absence | — |
| Example 3 | Sealing sheet 3 | Silicon oxide layer 1/“LUMIRROR” ™ X10S (125 μm)/ | Paint 1 | 0.1 | Paint 3 | 3.0 |
| | | Weather resistant coating layer | | | | |
| Example 4 | Sealing sheet 4 | Silicon oxide layer 1/“LUMIRROR” ™ E20 (125 μm)/ | Paint 1 | 0.1 | Paint 3 | 3.0 |
| | | Adhesion layer/“LUMIRROR” X10S | | | | |
| | | (125 μm)/Weather resistant coating layer | | | | |
| Example 5 | Sealing sheet 5 | Silicon oxide layer 1/Weather resistant coating layer/ | Paint 1 | 0.1 | Paint 3 | 3.0 |
| | | “LUMIRROR” ™ X10S (125 μm) | | | | |
| Comparative | Sealing sheet 6 | “LUMIRROR” ™ X10S (125 μm) | absence | — | absence | — |
| Example 1 | | | | | | |

TABLE 4

| | | Adhesive strength with silicone | | | |
|---|---|---|---|---|---|
| | | sealing material | | Color change after UV irradiation test | |
| | | | After moist heat | Irradiation on glass | Irradiation on sealing |
| | | Initial value | test | surface | sheet surface |
| Example No. | Sealing sheet | [N/10 mm] | [N/10 mm] | [symbol] b | [symbol] b |
| Example 1 | Sealing sheet 1 | 1.0 | 0.7 | 0.5 | 29.9 |
| Example 2 | Sealing sheet 2 | 2.0 | 0.7 | 0.5 | 29.9 |
| Example 3 | Sealing sheet 3 | 1.0 | 0.7 | 0.5 | 0.8 |
| Example 4 | Sealing sheet 4 | 2.5 | 0.7 | 0.2 | 0.8 |
| Example 5 | Sealing sheet 5 | 1.0 | 0.7 | 0.1 | 29.9 |
| Comparative | Sealing sheet 6 | 0.1 | 0.1 | 1.2 | 29.9 |
| Example 1 | | | | | |

### INDUSTRIAL APPLICABILITY

The method of producing a solar cell module is useful and the solar cell backside sealing sheet and the solar cell module are also useful because of their excellent adhesive strength with a silicone sealing material and excellent weather resistance.

1.-7. (canceled)

8. A method of producing a solar cell module comprising:
forming a silicon oxide layer by coating a paint containing at least one of silicate hydrolysis products and silica particles on at least one side of a base film; and
adhering said silicon oxide layer with a silicone sealing material layer.

9. The method according to claim 8, wherein said silicate is butyl silicate.

10. The method according to claim 8, wherein said base film contains an inorganic pigment.

11. The method according to claim 8, wherein said base film comprises an ultraviolet absorbent-containing resin layer on the opposite side of the surface on which said silicon oxide layer is formed.

12. The method according to claim 8, wherein said base film comprises an ultraviolet absorbent-containing resin layer and the surface on which said silicon oxide layer is formed is on the side of said resin layer.

13. A solar cell backside sealing sheet comprising a silicon oxide layer formed by coating a paint containing at least one of silicate hydrolysis products and silica particles on at least one side of a base film.

14. A solar cell module in which the silicon oxide layer according to claim 13 and a silicone sealing material layer are directly laminated.

15. The method according to claim 9, wherein said base film contains an inorganic pigment.

16. The method according to claim 9, wherein said base film comprises an ultraviolet absorbent-containing resin layer on the opposite side of the surface on which said silicon oxide layer is formed.

17. The method according to claim 10, wherein said base film comprises an ultraviolet absorbent-containing resin layer on the opposite side of the surface on which said silicon oxide layer is formed.

18. The method according to claim 9, wherein said base film comprises an ultraviolet absorbent-containing resin layer and the surface on which said silicon oxide layer is formed is on the side of said resin layer.

19. The method according to claim 10, wherein said base film comprises an ultraviolet absorbent-containing resin layer and the surface on which said silicon oxide layer is formed is on the side of said resin layer.

20. The method according to claim 11, wherein said base film comprises an ultraviolet absorbent-containing resin layer and the surface on which said silicon oxide layer is formed is on the side of said resin layer.
